(19) United States
(12) Patent Application Publication
(10) Pub. No.: US 2013/0295721 A1
(43) Pub. Date: Nov. 7, 2013

(54) APPARATUS TO FABRICATE FLIP-CHIP PACKAGES AND METHOD OF FABRICATING FLIP-CHIP PACKAGES USING THE SAME

(71) Applicant: SAMSUNG ELECTRONICS CO., LTD., Suwon-si (KR)

(72) Inventor: Ju-Hyun LYU, Cheonan-si (KR)

(73) Assignee: SAMSUNG ELECTRONICS CO,. LTD, Suwon-si (KR)

(21) Appl. No.: 13/785,893

(22) Filed: Mar. 5, 2013

(30) Foreign Application Priority Data
May 4, 2012 (KR) 10-2012-0047689

(51) Int. Cl. H01L 21/50

(52) U.S. Cl. CPC H01L 21/50
USPC 438/108

(57) ABSTRACT

An apparatus to fabricate a flip-chip package (FCP), and a method of fabricating an FCP using the same. The method includes providing a semiconductor chip such that an active surface on which a bump is formed faces upward, picking up the semiconductor chip using a pickup transfer and rotating the semiconductor chip such that the active surface of the semiconductor chip faces downward, directly transferring the semiconductor chip from the pickup transfer to a mount transfer, and mounting the semiconductor chip on a transfer unit using the mount transfer such that the active surface faces downward.

### CROSS-REFERENCE TO RELATED APPLICATIONS

This application claims priority under 35 U.S.C. §119 to Korean Patent Application No. 10-2012-0047689 filed on May 4, 2012, the disclosure of which is hereby incorporated by reference in its entirety.

### BACKGROUND OF THE INVENTION

1. Field of the Invention

Embodiments of the inventive concept relate to an apparatus to fabricate flip-chip packages (FCP) (hereinafter, FCP fabrication apparatus) and a method of fabricating FCPs using the same.

2. Description of the Related Art

A method of fabricating flip-chip packages (FCP) has been proposed to improve the productivity or quality of semiconductor devices.

### SUMMARY OF THE INVENTION

Embodiments of the inventive concept provide a flip-chip packages (FCP) fabrication apparatus.

Embodiments of the inventive concept provide an FCP fabrication apparatus and a method of fabricating FCP using the same.

Embodiments of the inventive concept provide an FCP fabrication apparatus including a plurality of nozzles to improve productivity, and a method of fabricating an FCP using the apparatus.

Embodiments of the inventive concept provide an FCP fabrication apparatus which may reduce the number of times nozzles are brought into contact with bump disposed on a surface of a semiconductor chip to increase throughput and improve quality, and a method of fabricating an FCP using the apparatus.

Aspects of the inventive concept should not be limited by the above description, and other unmentioned aspects will be clearly understood by one of ordinary skill in the art from example embodiments described herein.

Exemplary embodiments of the inventive concept provide a method of fabricating an FCP, the method including providing a semiconductor chip such that an active surface on which a bump is formed faces upward, picking up the semiconductor chip using a pickup transfer and rotating the semiconductor chip such that the active surface of the semiconductor chip faces downward, directly transferring the semiconductor chip from the pickup transfer to a mount transfer, and mounting the semiconductor chip on a transfer unit using the mount transfer such that the active surface faces downward.

The pickup transfer may include a pickup transfer head having a horizontal rotation axis and a pickup nozzle formed on a lower surface of the pickup transfer head and configured to vacuum-suck the semiconductor chip.

The pickup nozzle may include a pickup pad in direct contact with the active surface of the semiconductor chip and a pickup picker configured to move the pickup pad to raise and lower.

The picking up of the semiconductor chip using the pickup transfer may include aligning the pickup nozzle on the active surface of the semiconductor chip, lowering the pickup pad using the pickup picker into contact with the active surface of the semiconductor chip, vacuum-sucking the active surface of the semiconductor chip using the pickup pad, and raising the pickup pad using the pickup picker.

The rotation of the semiconductor chip using the pickup transfer such that the active surface of the semiconductor chip faces downward may include rotating the pickup transfer head about the rotation axis such that up and down portions of the pickup transfer head are inverted.

The mount transfer may include a mount head and a mount nozzle formed on a lower surface of the mount head and configured to vacuum-suck the semiconductor chip.

The mount nozzle may include a mount pad in direct contact with a rear surface disposed opposite the active surface of the semiconductor chip and a mount picker configured to raise and lower the mount pad.

The directly transferring the semiconductor chip from the pickup transfer to the mount transfer may include aligning the mount nozzle on the semiconductor chip having the rear surface facing upward, lowering the mount pad using the mount picker into contact with the rear surface of the semiconductor chip, vacuum-sucking the rear surface of the semiconductor chip using the mount pad, releasing the vacuum suction of the pickup nozzle, and raising the mount pad using the mount picker.

The mounting the semiconductor chip on the transfer unit using the mount transfer may include aligning the mount nozzle configured to vacuum-suck the semiconductor chip on the transfer unit, lowering the mount pad by which the semiconductor chip is vacuum-sucked on the transfer unit using the mount picker, releasing the vacuum suction of the mound pad, and raising the mount pad using the mount picker.

The aligning the mount nozzle on the transfer unit may further include recognizing the position of the semiconductor chip using a chip position recognition unit.

The chip position recognition unit may include a camera.

Before mounting the semiconductor chip on the transfer unit using the mount transfer, the method may include dipping a portion of the bump of the semiconductor chip in a flux using the mount transfer.

Exemplary embodiments of the inventive concept also provide a method of fabricating an FCP, the method including vacuum-sucking active surfaces of first and second semiconductor chips using first and second pickup nozzles adhered to a lower surface of a pickup transfer head, rotating the pickup transfer head such that the first and second pickup nozzles face upward, positioning a mount transfer head such that first and second mount nozzles are aligned with the first and second pickup nozzles on rear surfaces of the first and second semiconductor chips, transferring the first and semiconductor chips from the first and second pickup nozzles to the first and second mount nozzles, respectively, and mounting the first and second semiconductor chips on a transfer unit using the first and second mount nozzles.

The transferring the first and second semiconductor chips from the first and second pickup nozzles to the first and second mount nozzles may include vacuum-sucking the first semiconductor chip by bringing the first mount nozzle into contact with the first semiconductor chip vacuum-sucked on the first pickup nozzle, and releasing the vacuum suction of the first pickup nozzle, and vacuum-sucking the second semiconductor chip by bringing the second mount nozzle into contact with the second semiconductor chip vacuum-sucked on the second pickup nozzle, and releasing the vacuum suction of the second pickup nozzle.

The first and second pickup nozzles may be in direct contact with the active surfaces of the first and second semiconductor chips, and the pickup transfer head may rotate such that the active surfaces of the first and second semiconductor chips face downward, and rear surfaces of the first and second semiconductor chips face upward. The first and second mount nozzles of the mount head may be in direct contact with the rear surfaces of the first and second semiconductor chips, and the first and second semiconductor chips may be mounted on the transfer unit such that the active surfaces of the first and second semiconductor chips face downward.

Specific particulars of other embodiments are included in detailed descriptions and drawings.

Exemplary embodiments of the inventive concept also provide a method of fabricating a flip-chip package (FCP), comprising: vacuum sucking an active surface of a semiconductor chip and rotating the semiconductor chip using a first vacuum-sucking with a non-scratch surface such that the active surface of the semiconductor chip faces downward; directly transferring the semiconductor chip from the first vacuum-sucking to a second vacuum-sucking with a non-scratch surface being applied on an opposite surface of the semiconductor chip from the active surface; and mounting the semiconductor chip on a transfer unit using the second vacuum such that the active surface faces downward.

In an exemplary embodiment, the first vacuum-sucking may be performed with a pickup transfer and the second vacuum-sucking is performed with a mount transfer.

In another exemplary embodiment, the first vacuum-sucking the semiconductor chip using the pickup transfer may include: aligning a pickup nozzle of the pickup transfer on the active surface of the semiconductor chip; lowering a pickup pad of the pickup nozzle into contact with the active surface of the semiconductor chip; vacuum-sucking the active surface of the semiconductor chip using the pickup pad; and raising the pickup pad while vacuum-sucking the semiconductor chip.

In another exemplary embodiment, the directly transferring the semiconductor chip from the first vacuum-sucking to the second vacuum-sucking may include: aligning a mount nozzle of the mount transfer on the opposite surface of the semiconductor chip; lowering a mount pad of the mount nozzle into contact with the opposite surface of the semiconductor chip; vacuum-sucking the opposite surface of the semiconductor chip using the mount pad; releasing the first vacuum-sucking; and raising the mount pad while the second vacuum-sucking the semiconductor chip.

In another exemplary embodiment, the mounting the semiconductor chip on the transfer unit using the second vacuum-sucking comprises: aligning the mount nozzle configured to vacuum-suck the semiconductor chip on the transfer unit; lowering the mount pad by which the semiconductor chip is vacuum-sucked on the transfer unit; releasing the second vacuum-sucking; and raising the mount pad, wherein the aligning the mount nozzle on the transfer unit further includes a recognizing a position of the semiconductor chip using a chip position recognition unit.

### BRIEF DESCRIPTION OF THE DRAWINGS

The foregoing and other features and utilities of the inventive concept will be apparent from the particular description of exemplary embodiments of the inventive concept, as illustrated in the accompanying drawings in which like reference characters refer to the same parts throughout the different views. The drawings are not necessarily to scale, emphasis instead being placed upon illustrating the principles of the inventive concept. In the drawings:

FIG. 1 is a schematic block diagram of a flip-chip packages (FCP) fabrication apparatus of component according to an exemplary embodiment of the inventive concept;

FIG. 2 is a conceptual side view of an FCP fabrication apparatus according to an exemplary embodiment of the inventive concept;

FIGS. 3A through 3E are conceptual cross-sectional views illustrating a method of fabricating an FCP using an FCP fabrication apparatus according to an exemplary embodiment of the inventive concept;

FIGS. 4A through 4E are conceptual cross-sectional views illustrating a method of fabricating an FCP using an FCP fabrication apparatus according to an exemplary embodiment of the inventive concept;

FIGS. 5A through 5E are conceptual cross-sectional views illustrating a method of fabricating an FCP using an FCP fabrication apparatus according to an exemplary embodiment of the inventive concept; and

FIG. 6 is a conceptual flowchart illustrating a method of fabricating an FCP using an FCP fabrication apparatus according to an exemplary embodiment of the inventive concept.

### DETAILED DESCRIPTION OF THE PREFERRED EMBODIMENTS

The inventive concept will now be described more fully hereinafter with reference to the accompanying drawings, in which exemplary embodiments of the inventive concept are shown. This inventive concept may, however, be embodied in different forms and should not be construed as limited to the embodiments set forth herein. Rather, these embodiments are provided so that this disclosure is thorough and complete and fully conveys the scope of the inventive concept to one skilled in the art. In the drawings, the sizes and relative sizes of layers and regions are exaggerated for clarity. Like numbers refer to like element throughout. Thus, the same or similar numbers may be described with reference to other drawings even if they are neither mentioned nor described in the corresponding drawing. Also, even elements that are not denoted by reference numbers may be described with reference to other drawings.

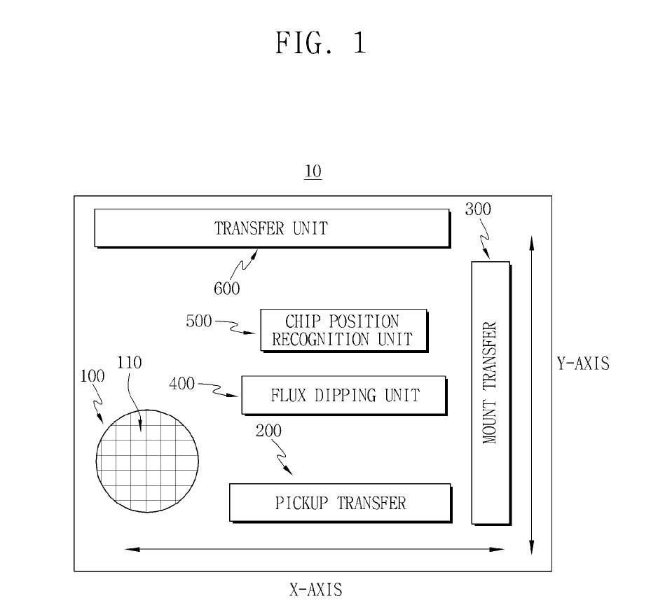

FIG. 1 is a schematic block diagram of an FCP fabrication apparatus 10 according to an exemplary embodiment of the inventive concept. Referring to FIG. 1, the FCP fabrication apparatus 10 may include a pickup transfer 200, a mount transfer 300, a flux dipping unit 400, a chip position recognition unit 500, and a transfer unit 600. To describe components of the FCP fabrication apparatus 10 according to the present embodiment of the inventive concept, a wafer 100 including a plurality of semiconductor chips 110 is also illustrated in FIG. 1.

The pickup transfer 200 may pick up a semiconductor chip 110 of a wafer 100 and transfer the semiconductor chip 110 to the mount transfer 300. The pickup transfer 200 may vacuum-suck the semiconductor chip 110. The pickup transfer 200 may move in an X direction.

The mount transfer 300 may directly receive the semiconductor chip 110 from the pickup transfer 200 and transfer the semiconductor chip 110 to the flux dipping unit 400. The mount transfer 300 may vacuum-suck the semiconductor chip 110. The mount transfer 300 may move in a Y direction.

The semiconductor chip 110 may be dipped to a uniformity thickness in a flux contained in the flux dipping unit 400 by the mount transfer 300.

The chip position recognition unit 500 may recognize a position of the semiconductor chip 110 such that the semiconductor chip 110 is positioned on the transfer unit 600.

The transfer unit 600 may receive the semiconductor chip 110 from the mount transfer 300 and move the semiconductor chip 110 to a position for a subsequent process.

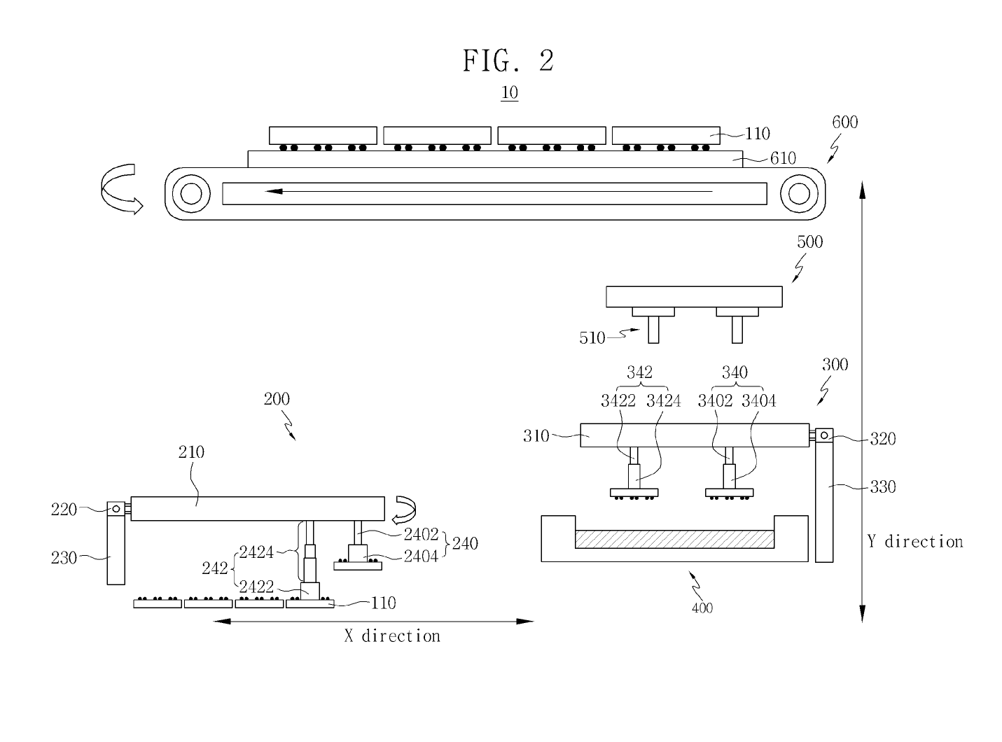

FIG. 2 is a conceptual side view of an FCP fabrication apparatus according to an exemplary embodiment of the inventive concept.

Referring to FIG. 2, a pickup transfer 200 may include a pickup transfer head 210, a pickup rotation axis 220, a pickup driver 230, and first and second pickup nozzles 240 and 242 configured to vacuum-suck semiconductor chips 110.

A lower surface of the pickup transfer head 210 may be connected to the first and second pickup nozzles 240 and 242, and one end portion of the pickup transfer head 210 may be connected to the pickup rotation axis 220. The pickup transfer head 210 may move up and down or from side to side, and directly transfer the semiconductor chips 110 picked by the first and second pickup nozzles 240 and 242 to the mount transfer 300. The pickup transfer head 210 may have a horizontal rotation axis and be rotated by an angle of about 180°.

The pickup rotation axis 220 may be capable of rotating at a high speed and rotate the pickup transfer head 210. The pickup rotation axis 220 may rotate by an angle of about 180° about an X-axial rotation axis.

The pickup driver 230 may move from side to side. The pickup driver 230 may move in an X direction level with the ground.

The first and second pickup nozzles 240 and 242 may be mounted on a lower side of the pickup transfer head 210 and vacuum-suck the semiconductor chip 110. The second pickup nozzle 242 may be spaced a uniform distance apart from the first pickup nozzle 240.

The first pickup nozzle 240 may include a first pickup picker 2402 and a first pickup pad 2404. The first pickup picker 2402, which may be formed between a lower side surface of the pickup transfer head 210 and the first pickup pad 2404, may raise and lower the first pickup pad 2404 and vacuum-suck and pick up the semiconductor chip 110. The first pickup picker 2402 may be pushed and pulled in a vertical direction to the ground.

The first pickup pad 2404 may be connected to a lower side surface of the first pickup picker 2402 and in direct contact with an active surface of the semiconductor chip 110. The first pickup pad 2404 may be formed of a cushion type material having an elasticity not to cause scratches to the semiconductor chip 110 during contact with the semiconductor chip 110. For example, the first pickup pad 2404 may be formed of urethane rubber or silicone rubber.

The second pickup nozzle 242 may include a second pickup picker 2422 and a second pickup pad 2424. The second pickup picker 2422, which may be formed between the lower side surface of the pickup transfer head 210 and the second pickup pad 2424, may raise and lower the second pickup pad 2424 and vacuum-suck and pick up the semiconductor chip 110. The second pickup picker 2422 may be pushed and pulled in a vertical direction to the ground.

The second pickup pad 2424 may be connected to a lower side surface of the second pickup picker 2422 and in direct contact with the active surface of the semiconductor chip 110. Similarly, the second pickup pad 2424 may be formed of a cushion type material having elasticity not to cause scratches to the semiconductor chip 110 during contact with the semiconductor chip 110. For instance, the second pickup pad 2424 may be formed of urethane rubber or silicone rubber.

The mount transfer 300 may include a mount transfer head 310, a mount rotation axis 320, a mount driver 330, and first and second mount nozzles 340 and 342 formed on a lower surface of the mount transfer head 310 and configured to vacuum-suck the semiconductor chip 110.

A lower surface of the mount transfer head 310 may be connected to the first and second mount nozzles 340 and 342, and one end portion of the mount transfer head 310 may be connected to the mount rotation axis 320. The mount transfer head 310 may move up and down and transfer the semiconductor chips 110.

The mount driver 330 may move up and down. The mount driver 330 may be parallel to the ground and move in a Y direction vertical to the X direction.

The first and second mount nozzles 340 and 342 may be formed on a lower side surface of the mount transfer head 310 and vacuum-suck the semiconductor chip 110. The second mount nozzle 342 may be spaced a uniform distance apart from the first mount nozzle 340.

The first mount nozzle 340 may include a first mount picker 3402 and a first mount pad 3404. The first mount picker 3402, which may be formed between the lower side surface of the mount transfer head 310 and the first mount pad 3404, may raise and lower the first mount pad 3404 and vacuum-suck and pick up the semiconductor chip 110. The first mount picker 3402 may be pushed and pulled in a vertical direction to the ground.

The first mount pad 3404 may be connected to a lower side surface of the first mount picker 3402 and in direct contact with a rear surface disposed opposite the active surface of the semiconductor chip 110. The first mount pad 3404 may be formed of a cushion type material having an elasticity not to cause scratches to the semiconductor chip 110 during contact with the semiconductor chip 110. For instance, the first mount pad 3404 may be formed of urethane rubber or silicone rubber.

The second mount nozzle 342 may include a second mount picker 3422 and a second mount pad 3424. The second mount picker 3422, which may be formed between the lower side surface of the mount transfer head 310 and the second mount pad 3424, may raise and lower the second mount pad 3424 and vacuum-suck and pick up the semiconductor chip 110. The second mount picker 3422 may be pushed and pulled in a vertical direction to the ground.

The second mount pad 3424 may be connected to a lower side surface of the second mount picker 3422 and in direct contact with a rear surface disposed opposite the active surface of the semiconductor chip 110. The second mount pad 3424 may be formed of a cushion type material having an elasticity not to cause scratches to the semiconductor chip 110 during contact with the semiconductor chip 110. For example, the second mount pad 3424 may be formed of urethane rubber or silicone rubber.

The chip position recognition unit 500 may include a camera 510 configured to recognize the position of the semiconductor chip 100. The camera 510 may be disposed on the center of a right side portion of an FCP fabrication apparatus 10. The camera 510 may be a single camera 510 or a plurality of cameras 510. The camera 510 may be a vision camera. The chip position recognition unit 500 may confirm an aligned state of the semiconductor chip 110 to increase the accuracy of the position of the semiconductor chip 110. The semiconductor chip 110 may be mounted on a substrate 610 of the transfer unit 600 based on a confirmation result obtained using the camera 510.

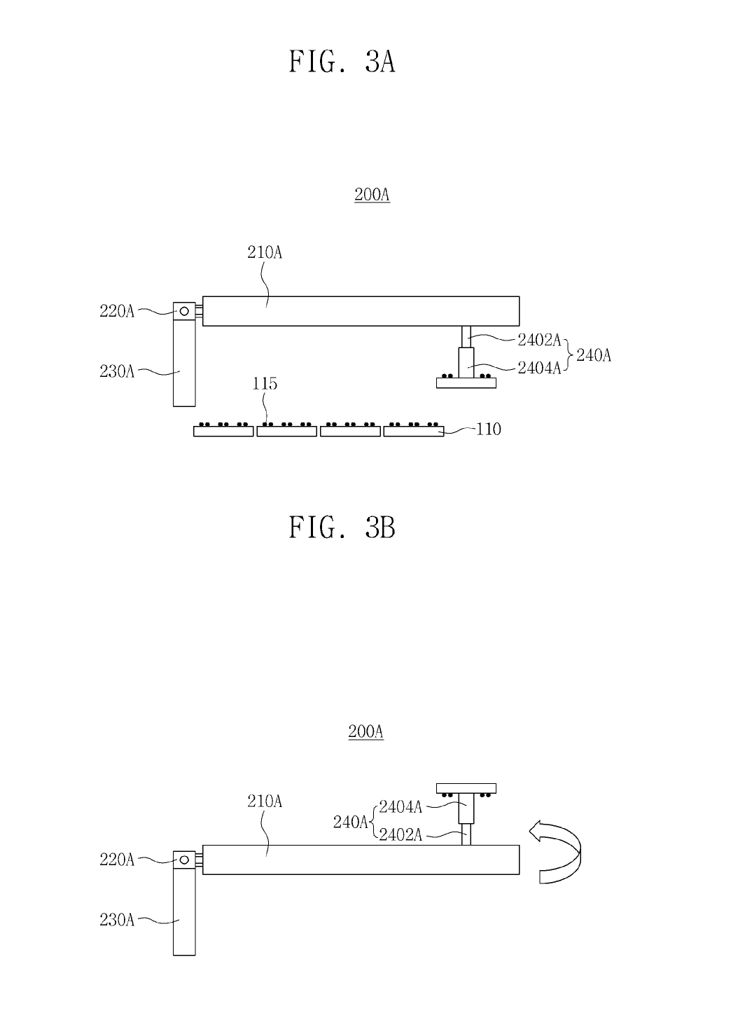

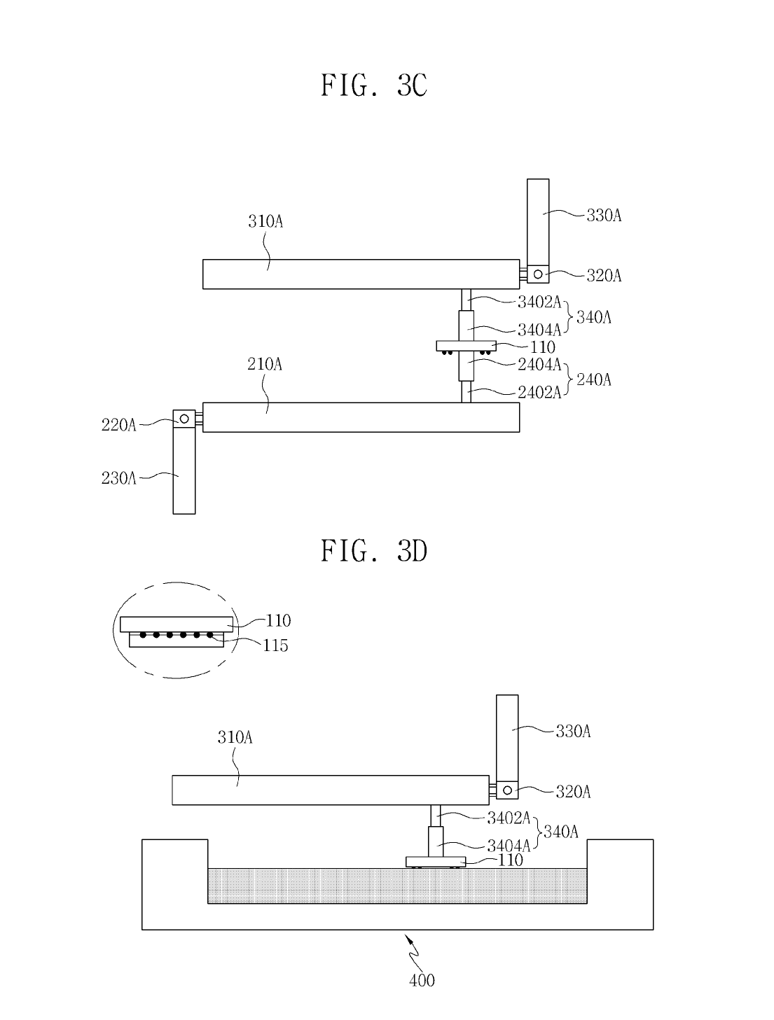

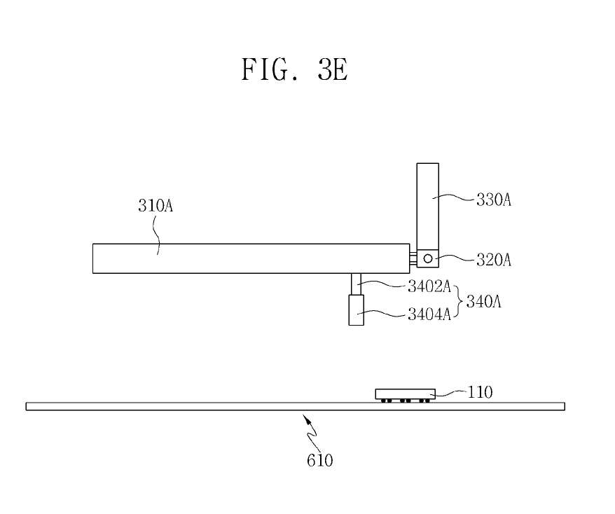

FIGS. 3A through 3E are conceptual cross-sectional views illustrating a method of fabricating an FCP using an FCP fabrication apparatus according to an exemplary embodiment of the inventive concept.

Referring to FIG. 3A, the method of fabricating the FCP using the FCP fabrication apparatus according to the present embodiment of the inventive concept may include picking up a semiconductor chip 110 using a pickup transfer 200A.

The picking up of the semiconductor chip 110 using the pickup transfer 200A may include aligning a pickup transfer head 210A on an active surface of the semiconductor chip 110, lowering a pickup pad 2404A using a pickup picker 2402A of a pickup nozzle 240A to vacuum-suck the semiconductor chip 110, and raising the pickup pad 2404A. One pickup nozzle 240A may pick up one semiconductor chip 110. The semiconductor chip 110 may be mounted such that an active surface on which a circuit is formed faces upward. That is, a bump(s) 115 may be exposed. Accordingly, a pickup nozzle 242A may be in contact with the active surface of the semiconductor chip 110 and a portion of the bump 115.

Referring to FIG. 3B, the method of fabricating the FCP using the apparatus of fabricating the FCP according to the present embodiment of the inventive concept may include rotating the pickup transfer head 210A such that the pickup nozzle 240A, which has picked up the semiconductor chip 110, faces upward. For example, the pickup transfer head 210A may rotate such that the active surface of the semiconductor chip 110 faces downward. The pickup transfer head 210A may rotate by an angle of about 180° about a pickup rotation axis 220A such that upper and lower portions of the pickup transfer head 210A are inverted.

Referring to FIG. 3C, the method of fabricating the FCP using the FCP fabrication apparatus according to the present embodiment of the inventive concept may include directly transferring the semiconductor chip 110 from the pickup transfer 200A to a mount transfer 300A.

The pickup transfer head 210A may horizontally move toward the mount transfer 300A. For instance, a pick driver 230A may horizontally move the pickup transfer head 210A and align the pickup transfer head 210A under a mount transfer head 310A.

A mount nozzle 340A may receive the semiconductor chip 110 from the pickup pad 2404A of the pickup transfer 200A. For example, after the mount transfer head 310A is aligned on the pickup transfer head 210A, a mount picker 3402A of the mount nozzle 340A may lower the mount pad 2404A and be in contact with a rear surface of the semiconductor chip 110. That is, the mount picker 3402A may vacuum-suck the rear surface of the semiconductor chip 110, and raise the mount pad 3404A together with the semiconductor chip 110. Subsequently, vacuum suction of the pickup nozzle 240A may be released, and the mount nozzle 340A may vacuum-suck the semiconductor chip 110.

Referring to FIG. 3D, the method of fabricating the FCP using the apparatus of fabricating the FCP according to the present embodiment of the inventive concept may include transferring the semiconductor chip 110 to the flux dipping unit 400 and dipping portions of the bump(s) 115 formed on the semiconductor chip 110 in a flux. For instance, the method may include dipping portions of the bump(s) 115 formed on the semiconductor chip 110 in a flux. A dipping time may be less than about several seconds. For example, the dipping time may be about 0.1 to 1.0 second.

Referring to FIG. 3E, the method of fabricating the FCP using the apparatus of fabricating the FCP according to the present embodiment of the inventive concept may include mounting the semiconductor chip 110 on a substrate 610 of a transfer unit 600 using the mount transfer 300A. For instance, the method may include transferring the mount transfer head 310A using a mount driver 330A to align the mount transfer head 310A on the substrate 610 of the transfer unit 600, lowering the mount pad 3404A, which has vacuum-sucked the semiconductor chip 110, to the substrate 610 of the transfer unit 600 using the mount picker 3402A, releasing the vacuum suction of the mount pad 3404A, and raising the mount pad 3404A using the mount picker 3402A.

The transfer unit 600 may move the semiconductor chip 110 mounted on the substrate 610 to a position for a subsequent process.

According to the inventive concept, physical stress applied to the active surface of the semiconductor chip 110 and the bump 115 may be minimized. For instance, the active surface of the semiconductor chip 110 and the bump(s) 115 may be in contact with the pickup nozzle 242A only once and mounted on the substrate 610 of the transfer unit 600.

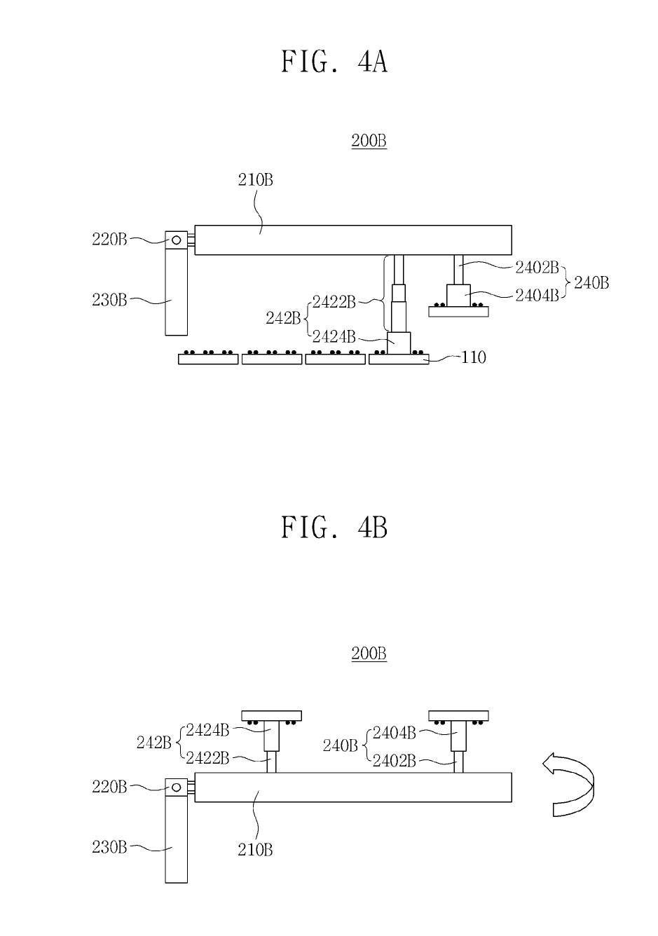

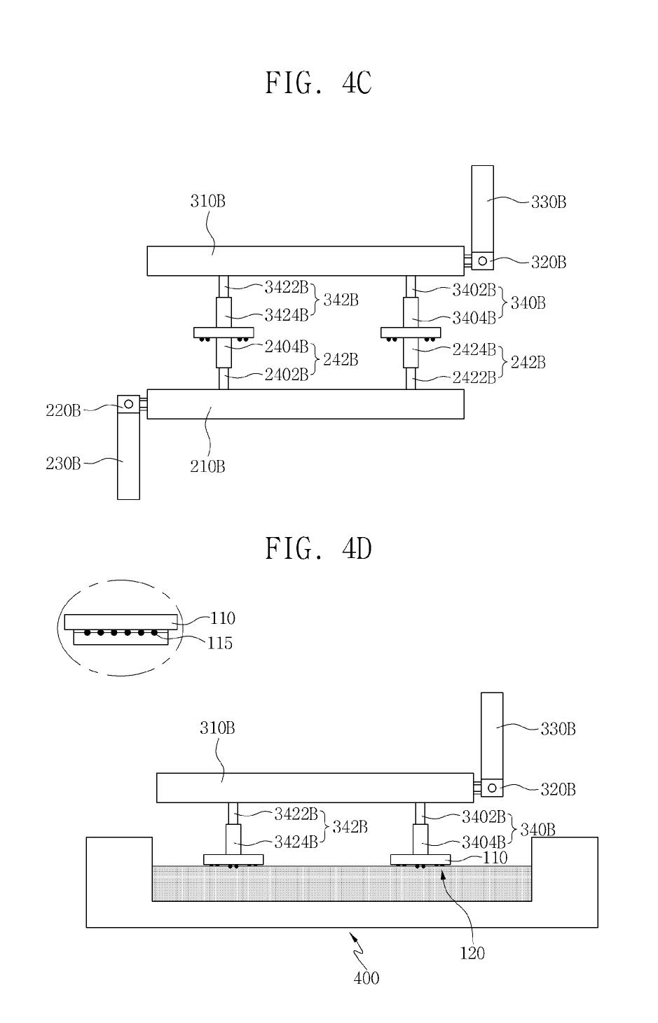

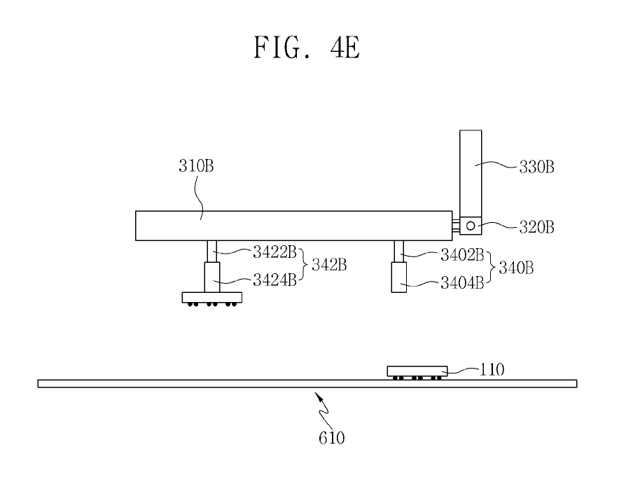

FIGS. 4A through 4E are conceptual cross-sectional views illustrating a method of fabricating an FCP using an FCP fabrication apparatus according to another exemplary embodiment of the inventive concept.

Referring to FIG. 4A, the method of fabricating the FCP using the FCP fabrication apparatus according to the present embodiment of the inventive concept may include sequentially picking up two semiconductor chips 110 using a pickup transfer 200B including first and second pickup nozzles 240B and 242B. The picking up of the semiconductor chip 110 using the pickup transfer 200B may include lowering a first pickup pad 2404B using a first pickup picker 2402B of the first pickup nozzle 240B to vacuum-suck an active surface of the semiconductor chip 110, and raising the first pickup pad 2404B. Subsequently, the method may include lowering a second pickup pad 2424B using a second pickup picker 2422B of the second pickup nozzle 242B to vacuum-suck the active surface of the semiconductor chip 110, and raising the second pickup pad 2424B. After the second pickup nozzle 242B picks up one semiconductor chip 110, the first pickup nozzle 240B may pick up one semiconductor chip 110.

Referring to FIG. 4B, the method of fabricating the FCP using the FCP fabrication apparatus according to the present embodiment of the inventive concept may include rotating the pickup transfer head 210B such that the first and second pickup nozzles 240B and 242B, which have picked up the respective semiconductor chip 110, face upward. For instance, the pickup transfer head 210B may rotate such that the active surface of the semiconductor chip 110 faces downward. The pickup transfer head 210B may rotate by an angle of about 180° about the pickup rotation axis 220B such that upper and lower portions of the pickup transfer head 210B are inverted.

Referring to FIG. 4C, the method of fabricating the FCP using the FCP fabrication apparatus according to the present embodiment of the inventive concept may include directly transferring two semiconductor chips 110 from the pickup transfer 200B to a mount transfer 300B including first and second mount nozzles 340B and 342B.

The first mount nozzle 340B may receive the semiconductor chip 110 from the second pickup 2424B of the pickup transfer 200B, while the second mount nozzle 342B may receive the first pickup pad 2404B of the pickup transfer 200B. For example, a first mount picker 3402B of the first mount nozzle 340B may lower a first mount pad 3404B to vacuum-suck a rear surface of the semiconductor chip 110, and raise the first mount pad 3404B. Subsequently, the vacuum suction of the second pickup nozzle 242B may be released, and the first mount nozzle 340B may vacuum-suck the semiconductor chip 110.

Next, a second mount picker 3422B of the second mount nozzle 342B may lower a second mount pad 3424B to vacuum-suck the rear surface of the semiconductor chip 110, and raise the second mount pad 3424B. Subsequently, the vacuum suction of the first pickup nozzle 240B may be released, and the second mount nozzle 342B may vacuum-suck the semiconductor chip 110.

Referring to FIG. 4D, the method of fabricating the FCP using the FCP fabrication apparatus according to the present embodiment of the inventive concept may include transferring the semiconductor chip 110 using the mount transfer 300B to a flux dipping unit 400 and dipping portions of bumps 115 formed on semiconductor chips 110 in a flux.

Referring to FIG. 4E, the method of fabricating the FCP using the FCP fabrication apparatus according to the present embodiment of the inventive concept may include sequentially mounting two semiconductor chips 110 on a substrate 610 of a transfer unit 600 using the mount transfer 300B. For example, the method may include lowering the first mount nozzle 340B to mount the semiconductor chips 110 on the substrate 610, releasing the vacuum suction of the first mount nozzle 340B, raising the first mount nozzle 340B, lowering the second mount nozzle 342B to mount the semiconductor chips 110 on the substrate 610, releasing the vacuum suction of the second mount nozzle 342B, and raising the second mount nozzle 342B. Alternatively, after the second mount nozzle 342B firstly lowers, mounts the semiconductor chips 110 on the substrate 610, and raises, the first mount nozzle 340B may lower, mount the semiconductor chips 110 on the substrate 610, and raise.

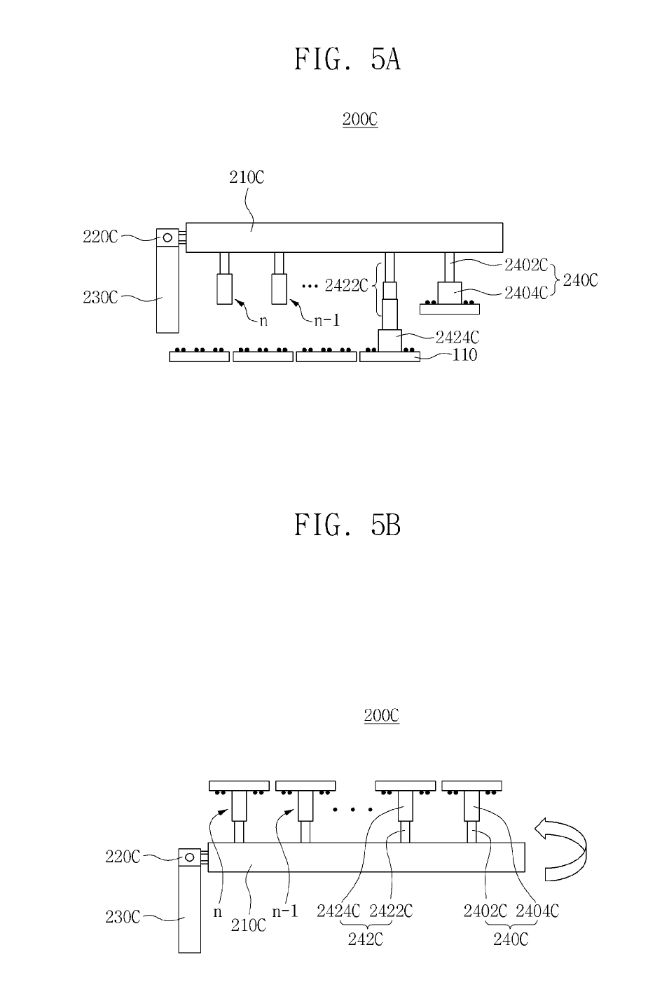

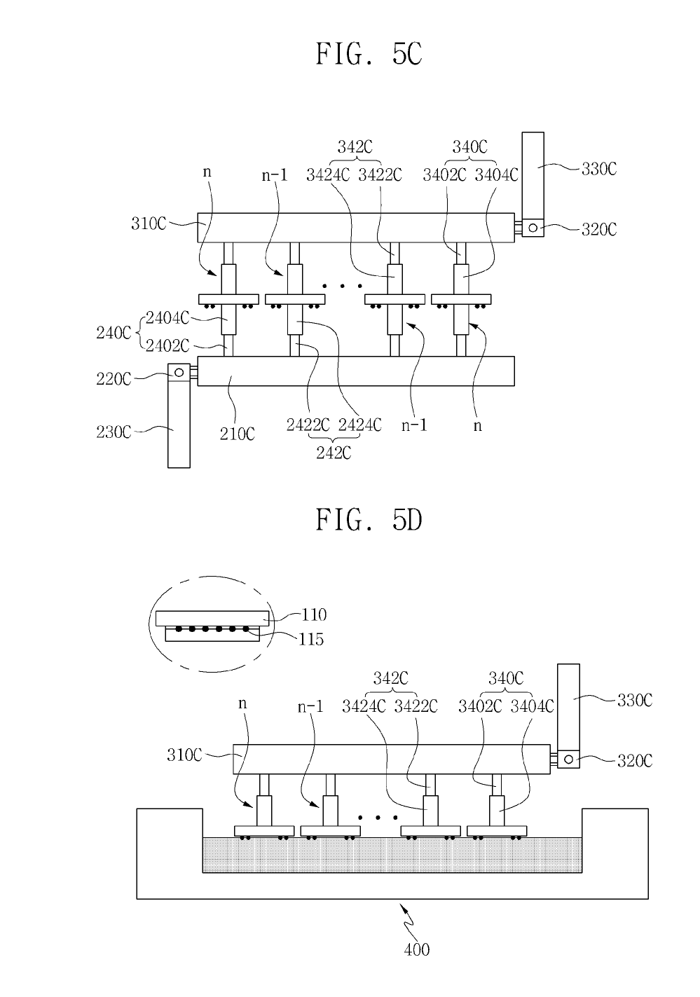

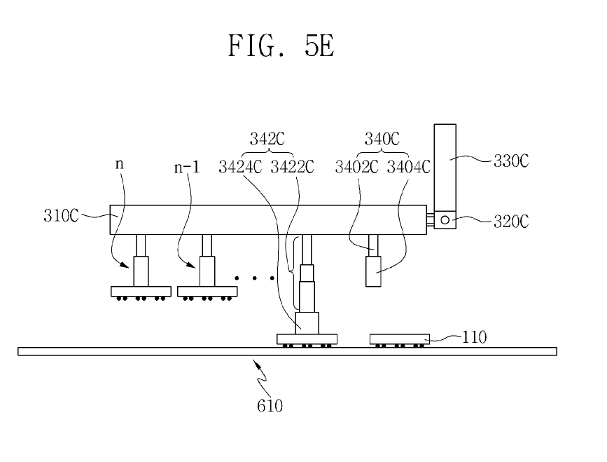

FIGS. 5A through 5E are conceptual cross-sectional views illustrating a method of fabricating an FCP using an FCP fabrication apparatus according to another exemplary embodiment of the inventive concept.

Referring to FIG. 5A, the method of fabricating the FCP using the FCP fabrication apparatus according to the present embodiment of the inventive concept may include sequentially picking active surfaces of a plurality of semiconductor chips 110 using a pickup transfer 200C including a plurality of pickup nozzles 240C-n. A first pickup nozzle 240C may pick up a semiconductor chip 110, a second pickup nozzle 242C may pick up the semiconductor chip 110, an n−1-th pickup nozzle n−1 may pick up the semiconductor chip 110, and an n-th pickup nozzle n may pick up the semiconductor chip 110. The number of the plurality of pickup nozzles 240C-n may be equal to the number of the picked-up semiconductor chips 110.

Referring to FIG. 5B, the method of fabricating the FCP using the FCP fabrication apparatus according to the present embodiment of the inventive concept may include rotating a pickup transfer head 210C such that a plurality of pickup nozzles 240C-n, which have picked up the semiconductor chips 110, face upward. For instance, the pickup transfer head 210C may rotate such that active surfaces of the semiconductor chips 110 face downward. The pickup transfer head 210C may rotate by an angle of about 180° about a pickup rotation axis 220C such that upper and lower portions of the pickup transfer head 210C are inverted.

Referring to FIG. 5C, the method of fabricating the FCP using the FCP fabrication apparatus according to the present embodiment of the inventive concept may include sequentially and directly transferring a plurality of semiconductor chips 110 from a pickup transfer 200C to the mount transfer 300B including a plurality of mount nozzles 240C-n.

A first mount nozzle 340C may receive the semiconductor chip 110 from an n-th pickup nozzle n of the pickup transfer 200C, a second mount nozzle 342C may receive the semiconductor chip 110 from an n−1-th pickup nozzle n−1 of the pickup transfer 200C, an n−1 mount nozzle may receive the semiconductor chip from the second pickup nozzle 242C of the pickup transfer 200C, and an n-th mount nozzle n may receive the semiconductor chip 110 from the first pickup nozzle 240C of the pickup transfer 200C.

Referring to FIG. 5D, the method of fabricating the FCP using the FCP fabrication apparatus according to the present embodiment of the inventive concept may include transferring the semiconductor chip 110 to the flux dipping unit 400 to dip portions of the semiconductor chips 110 in a flux using a mount transfer 300C. For example, the method may include dipping portions of the bumps 115 formed on the semiconductor chips 110 in a flux.

Referring to FIG. 5E, the method of fabricating the FCP using the FCP fabrication apparatus according to the present embodiment of the inventive concept may include sequentially mounting a plurality of semiconductor chips 110 on the substrate 610 of the transfer unit 600 using a mount transfer 300C.

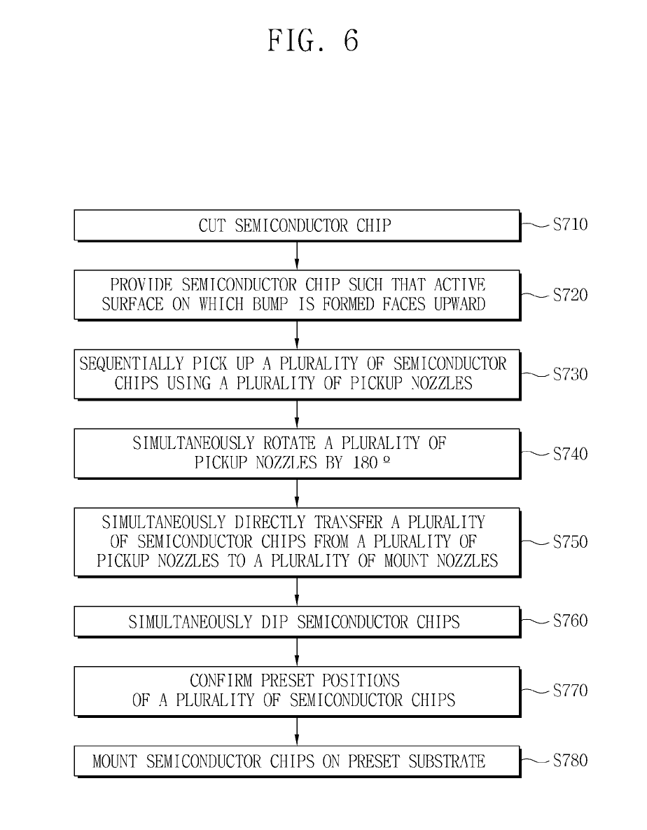

FIG. 6 is a conceptual flowchart illustrating a method of fabricating an FCP using an FCP fabrication apparatus according to an exemplary embodiment of the inventive concept.

Referring to FIGS. 1, 2, and 6, the method of fabricating the FCP using the FCP fabrication apparatus 10 according to the present embodiment of the inventive concept may include cutting a wafer 100 into unit semiconductor chips 110 (operation S710). For instance, the cutting the wafer 100 may include sawing the wafer 100. The cut wafer with the semiconductor chips 110 is illustrated in FIG. 1.

The method of fabricating the FCP according to the present embodiment of the inventive concept may include providing the semiconductor chips 110 such that active surfaces on which bumps 115 are formed face upward (operation S720). See FIG. 2 for illustration of the chips 110 facing upward.

The method of fabricating the FCP according to the present embodiment of the inventive concept may include sequentially picking up the plurality of semiconductor chips 110 using a plurality of pickup nozzles 240 of a pickup transfer 200 (operation S730).

Next, the pickup transfer 200 may include simultaneously rotating the plurality of pickup nozzles 240 by an angle of about 180° about a pickup rotation axis 220 (operation S740). For example, a pickup transfer head 210 may rotate by about 180° about a pickup rotation axis 220 such that upper and lower portions of the pickup transfer head 210 are inverted.

The method of fabricating the FCP according to the present exemplary embodiment of the inventive concept may include vacuum-sucking the plurality of semiconductor chips 110 from the plurality of pickup nozzles 240 using a plurality of mount nozzles 340 of a mount transfer 300 and simultaneously directly transferring the plurality of semiconductor chips 110 to the plurality of mount nozzles 340 of the mount transfer 300 (operation S750).

The method of fabricating the FCP according to the present exemplary embodiment of the inventive concept may include simultaneously dipping uniform portions of bump 115 of the plurality of semiconductor chips 110 transferred to the mount transfer 300 in a flux filling a flux dipping unit 400 (operation S760).

The method of fabricating the FCP according to the present exemplary embodiment of the inventive concept may include confirming preset positions of the plurality of dipped semiconductor chips 110 using a camera 510 (operation S770).

The method of fabricating the FCP according to the present exemplary embodiment of the inventive concept may include mounting the semiconductor chips 110 on a preset substrate 610 using a mount transfer 300 (operation S780).

According to an FCP fabrication apparatus and exemplary methods of fabricating an FCP according various embodiments of the inventive concept, the FCP fabrication apparatus can include a plurality of nozzles to improve productivity. Also, the number of times the FCP fabrication apparatus is in contact with the semiconductor chip and bumps of the semiconductor chip may be minimized to increase throughput and reduce damage to the bumps, thereby improving the quality of devices.

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures.

What is claimed is:

1. A method of fabricating a flip-chip package (FCP), comprising:
providing a semiconductor chip such that an active surface on which a bump is formed faces upward;
picking up the semiconductor chip using a pickup transfer and rotating the semiconductor chip such that the active surface of the semiconductor chip faces downward;
directly transferring the semiconductor chip from the pickup transfer to a mount transfer; and
mounting the semiconductor chip on a transfer unit using the mount transfer such that the active surface faces downward.

2. The method of claim 1, wherein the pickup transfer comprises:
a pickup transfer head having a horizontal rotation axis; and
a pickup nozzle formed on a lower surface of the pickup transfer head and configured to vacuum-suck the semiconductor chip.

3. The method of claim 2, wherein the pickup nozzle comprises:
a pickup pad in direct contact with the active surface of the semiconductor chip; and
a pickup picker configured to move the pickup pad to raise and lower.

4. The method of claim 3, wherein the picking up the semiconductor chip using the pickup transfer comprises:
aligning the pickup nozzle on the active surface of the semiconductor chip;
lowering the pickup pad using the pickup picker into contact with the active surface of the semiconductor chip;
vacuum-sucking the active surface of the semiconductor chip using the pickup pad; and
raising the pickup pad using the pickup picker.

5. The method of claim 2, wherein the rotating the semiconductor chip using the pickup transfer such that the active surface of the semiconductor chip faces downward comprises:
rotating the pickup transfer head about the rotation axis such that upper and lower portions of the pickup transfer head are inverted.

6. The method of claim 1, wherein the mount transfer comprises:
a mount head; and
a mount nozzle formed on a lower surface of the mount head and configured to vacuum-suck the semiconductor chip.

7. The method of claim 6, wherein the mount nozzle comprises:
a mount pad in direct contact with a rear surface disposed opposite the active surface of the semiconductor chip; and
a mount picker configured to raise and lower the mount pad.

8. The method of claim 3, wherein the directly transferring the semiconductor chip from the pickup transfer to the mount transfer comprises:
aligning the mount nozzle on the semiconductor chip having the rear surface facing upward;
lowering the mount pad using the mount picker into contact with the rear surface of the semiconductor chip;
vacuum-sucking the rear surface of the semiconductor chip using the mount pad;
releasing the vacuum suction of the pickup nozzle; and
raising the mount pad using the mount picker.

9. The method of claim 7, wherein the mounting the semiconductor chip on the transfer unit using the mount transfer comprises:
aligning the mount nozzle configured to vacuum-suck the semiconductor chip on the transfer unit;
lowering the mount pad by which the semiconductor chip is vacuum-sucked on the transfer unit using the mount picker;
releasing the vacuum suction of the mound pad; and
raising the mount pad using the mount picker.

10. The method of claim 9, wherein the aligning the mount nozzle on the transfer unit further comprises:
recognizing a position of the semiconductor chip using a chip position recognition unit.

11. The method of claim 10, wherein the chip position recognition unit includes a camera.

12. The method of claim 1, further comprising:
before mounting the semiconductor chip on the transfer unit using the mount transfer, dipping a portion of the bump of the semiconductor chip in a flux using the mount transfer.

13. A method of fabricating a flip-chip package (FCP), comprising:
vacuum-sucking active surfaces of first and second semiconductor chips using first and second pickup nozzles adhered to a lower surface of a pickup transfer head;
rotating the pickup transfer head such that the first and second pickup nozzles face upward;
positioning a mount transfer head such that first and second mount nozzles are aligned with the first and second pickup nozzles on rear surfaces of the first and second semiconductor chips;
transferring the first and semiconductor chips from the first and second pickup nozzles to the first and second mount nozzles, respectively; and
mounting the first and second semiconductor chips on a transfer unit using the first and second mount nozzles.

14. The method of claim 13, wherein the transferring the first and second semiconductor chips from the first and second pickup nozzles to the first and second mount nozzles comprises:
vacuum-sucking the first semiconductor chip by bringing the first mount nozzle into contact with the first semiconductor chip vacuum-sucked on the first pickup nozzle, and releasing the vacuum suction of the first pickup nozzle; and
vacuum-sucking the second semiconductor chip by bringing the second mount nozzle into contact with the second semiconductor chip vacuum-sucked on the second pickup nozzle, and releasing the vacuum suction of the second pickup nozzle.

15. The method of claim 13, wherein the first and second pickup nozzles are in direct contact with the active surfaces of the first and second semiconductor chips,
the pickup transfer head rotates such that the active surfaces of the first and second semiconductor chips face downward, and rear surfaces of the first and second semiconductor chips face upward,
the first and second mount nozzles of the mount head are in direct contact with the rear surfaces of the first and second semiconductor chips, and
the first and second semiconductor chips are mounted on the transfer unit such that the active surfaces of the first and second semiconductor chips face downward.

16. A method of fabricating a flip-chip package (FCP), comprising:
vacuum sucking an active surface of a semiconductor chip and rotating the semiconductor chip using a first vacuum-sucking with a non-scratch surface such that the active surface of the semiconductor chip faces downward;
directly transferring the semiconductor chip from the first vacuum-sucking to a second vacuum-sucking with a non-scratch surface being applied on an opposite surface of the semiconductor chip from the active surface; and
mounting the semiconductor chip on a transfer unit using the second vacuum-sucking such that the active surface of the semiconductor chip faces downward.

17. The method of claim 16, wherein the first vacuum-sucking is performed with a pickup transfer and the second vacuum-sucking is performed with a mount transfer.

18. The method of claim 17, wherein the first vacuum-sucking the semiconductor chip using the pickup transfer comprises:
aligning a pickup nozzle of the pickup transfer on the active surface of the semiconductor chip;
lowering a pickup pad of the pickup nozzle into contact with the active surface of the semiconductor chip;
vacuum-sucking the active surface of the semiconductor chip using the pickup pad; and
raising the pickup pad while vacuum-sucking the semiconductor chip.

19. The method of claim 17, wherein the directly transferring the semiconductor chip from the first vacuum-sucking to the second vacuum-sucking comprises:
aligning a mount nozzle on the opposite side of the semiconductor chip;
lowering a mount pad of the mount nozzle into contact with the opposite surface of the semiconductor chip;
vacuum-sucking the opposite surface of the semiconductor chip using the mount pad;
releasing the first vacuum sucking; and
raising the mount pad while the second vacuum-sucking the semiconductor chip.

20. The method of claim 19, wherein the mounting the semiconductor chip on the transfer unit using the second vacuum-sucking comprises:
aligning the mount nozzle configured to vacuum-suck the semiconductor chip on the transfer unit;
lowering the mount pad by which the semiconductor chip is vacuum-sucked on the transfer unit;
releasing the second vacuum-sucking; and
raising the mount pad,
wherein the aligning the mount nozzle on the transfer unit further includes a recognizing a position of the semiconductor chip using a chip position recognition unit.
